(19) United States
(12) Patent Application Publication
(10) Pub. No.: US 2003/0115528 A1
(43) Pub. Date: Jun. 19, 2003

(54) Semiconductor memory device capable of failure analysis with system in operation

(75) Inventors: Shinji Tanaka, Hyogo (JP); Takahiko Fukiage, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/175,845

(22) Filed: Jun. 21, 2002

(30) Foreign Application Priority Data
Dec. 14, 2001 (JP) 2001-381274 (P)

(51) Int. Cl. G06F 11/00; G01R 31/28

(52) U.S. Cl. 714/742

(57) ABSTRACT

In accordance with a voltage impressed to NC pins 1 and 2 unused by the system of interest a debug mode control circuit activates a reference voltage generation circuit, a data input/output circuit, an internal signal monitor circuit and a signal history record and output circuit selectively in a debug mode. When activated in the debug mode, the reference voltage generation circuit sets an internal power supply voltage to have a level of an external power supply voltage to internally supply power. The data input/output circuit reduces an ability to drive outputting data. The internal signal monitor circuit monitors any internal signal, and the signal history record and output circuit records a history in variation of any internal signal and outputs it to the debug mode control circuit. Thus there can be provided a semiconductor memory device capable of failure analysis without affecting the system operation.

### BACKGROUND OF THE INVENTION

1. Field of the Invention

The present invention relates generally to semiconductor memory devices and particularly to those mounted on a system and still capable of analyzing a failure when the system is in operation.

2. Description of the Background Art

Semiconductor memory devices are frequently used as temporary storage device of personal computers. As personal computers have increased rates of operation and higher levels of integration, a significantly unsteady failure can be introduced on the system. Removing the semiconductor memory device from the system and examining the device to analyze the failure in detail does not always ensure that the failure is readily reproduced.

To facilitate detection of a marginal failure providing a small margin for steady operation, a conventionally known semiconductor memory device has a test mode such as increasing an internal voltage to apply a stress, and mounted on a system is capable of testing for the marginal failure.

Another known semiconductor memory device has a test mode capable of providing a smaller driving ability of a data input/output circuit than in a normal mode of operation to detect a marginal failure related to inputting and outputting data.

FIG. 17 is a functional block diagram for functionally illustrating a conventional semiconductor memory device having such a test mode.

As shown in FIG. 17, a semiconductor memory device 200 includes a reference voltage generation circuit 201, an internal voltage generation circuit 202, a data input/output circuit 203, an address decode circuit 204, and an internal control circuit 205.

Reference voltage generation circuit 201 generates a reference voltage Vref serving as a reference for an internal power supply voltage generated by internal voltage generation circuit 202 and outputs reference voltage Vref to internal voltage generation circuit 202. When internal control circuit 205 outputs a test mode signal TM having a logical high level, reference voltage generation circuit 201 outputs to internal voltage generation circuit 202 reference voltage Vref having a voltage level higher than an internal power supply voltage provided in a normal mode of operation. Typically, reference voltage Vref is set to be lower than an external power supply voltage. As such reference voltage generation circuit 202 outputs reference voltage Vref for example at the voltage level of the external power supply voltage.

In accordance with reference voltage Vref received from reference voltage generation circuit 201, internal voltage generation circuit 202 converts the external power supply voltage to an internal power supply voltage and outputs it to each circuit internal to semiconductor memory device 200. In semiconductor memory device 200, when the test mode is active, internal voltage generation circuit 202 generates the internal power supply voltage based on reference voltage Vref having a higher voltage level than in the normal mode of operation and a test accelerating a marginal failure is thus conducted.

Data input/output circuit 203 is a buffer circuit allowing external data communication. When internal control circuit 205 outputs test mode signal TM having the high level, data input/output circuit 203 in outputting data operates to provide a smaller amount of electric current to data input/output pins DQ0-DQm than in the normal mode of operation to reduce an ability to drive externally outputting internal data. Thus, in semiconductor memory device 200, when the test mode is active, a test is acceleratively conducted for data input/output circuit 203 for a marginal failure.

Address decode circuit 204 latches externally received address signals A0-An and internally outputs an address signal. Furthermore, when pin A0 has been impressed thereto a voltage having a predetermined level or more in voltage, address decode circuit 204 generates a signal serving as one condition activating the test mode and outputs the signal to internal control circuit 205.

FIG. 17 only shows a circuit diagram related to the latter's function, and address decode circuit 204 includes a p-channel MOS transistors 2041, 2042, a resistor 2043, an inverter 2044, an external power supply node 2045, a ground node 2046, and nodes 2047, 2048.

P-channel MOS transistor 2041 is diode-connected and has its source connected to address signal pin A0. P-channel MOS transistor 2042 is connected between p-channel MOS transistor 2041 and resistor 2043 and has its gate connected to external power supply node 2045. To node 2048 inverter 2044 is connected and its output is received by internal control circuit 205.

Herein, p-channel MOS transistor 2042 does not turn on when node 2047 has a voltage less than an external power supply voltage ext.Vcc plus a threshold voltage, represented by VT, of p-channel MOS transistors 2041, 2042. Furthermore, p-channel MOS transistor 2041 does not turn on when pin A0 has been impressed thereto a voltage, represented by VA0, less than the node 2047 voltage plus VT.

In other words, address decode circuit 204 is configured to allow node 2048 to have the high level when voltage VA0 is no less than a voltage ext.Vcc+2VT. Thus when pin A0 has been impressed thereto a voltage satisfying VA0≧ext.Vcc+2VT address decode circuit 204 outputs a signal of a logically low level to internal control circuit 205.

Internal control circuit 205 includes an NOR gate 2051 having inputs receiving externally received control signals/CS, /RAS, /CAS and /WE and a signal output from address decode circuit 204. When control signals/CS, /RAS, /CAS and AWE and the signal from address decode circuit 204 all have the low level, internal control circuit 205 determines that a test mode is entered and internal control circuit 205 sets test mode signal TM high and outputs the signal to reference voltage generation circuit 201 and data input/output circuit 203.

In semiconductor memory device 200 when pin A0 has been impressed thereto a voltage of no less than external power supply voltage ext.Vcc plus 2VT and control signals/CS, /RAS, /CAS and /WE all have the low level internal control circuit 205 determines that the test mode is entered and internal control circuit 205 outputs test mode signal TM of the high level to reference voltage generation circuit 201 and data input/output circuit 203.

When test mode signal TM has the high level, reference voltage generation circuit 201 outputs reference voltage Vref to internal voltage generation circuit 202 at the voltage level of the external power supply voltage, which is higher than Vref provided in the normal mode of operation. In accordance with reference voltage Vref received from reference voltage generation circuit 201 internal voltage generation circuit 202 generates an internal power supply voltage of the external power supply voltage level and outputs it to each circuit. Thus in the test mode of operation an internal power supply higher than in the normal mode of operation is supplied and the test for the failure is accelerated.

When test mode signal TM has the high level, data input/output circuit 203 operates such that an output circuit has a smaller ability to drive externally outputting internal data than in the normal mode of operation. Thus in the test mode of operation a test is conducted for a marginal failure related to outputting data.

In semiconductor memory device 200 as described above, however, control signals/CS, /RAS, /CAS and /WE and address signal A0 are all signals used in a system in a normal mode of operation, and arbitrarily impressing a voltage to these input pins externally to operate the semiconductor memory device is not desirable as such can introduce serious system failure.

### SUMMARY OF THE INVENTION

The present invention has been made to overcome the disadvantage as described above and it contemplates a semiconductor memory device mounted on a system and still capable of sifting to a test mode in response to an external signal and analyzing a failure with the system in operation without affecting the system operation.

Furthermore, selecting a test mode entails externally inputting a mode select signal through any of terminals, and if there are a large number of test modes and in proportion thereto there also exists a large number of terminals required to input such mode select signals, some physical limitation would presumably be imposed on the number of terminals of the semiconductor memory device of interest and it is in effect impossible to provide a sufficient number of test modes.

Therefore the present invention contemplates a semiconductor memory device operable on a system in response to an external signal to shift to a test mode in response to a mode select signal externally received through a minimized number of terminals.

The present invention provides a semiconductor memory device capable of failure analysis while the semiconductor memory device is in operation, including: a plurality of terminals capable of externally communicating a power supply voltage, data and a signal; an internal circuit effecting a predetermined operation in response to an externally received signal; and a debug mode control circuit activated in response to a level of a voltage received at a terminal unused by the system in a normal operation, to generate and output to the internal circuit a debug mode activation signal enabling the semiconductor memory device in a debug mode. Wherein, the internal circuit is operative in response to the debug mode activation signal to effect the predetermined operation and meanwhile shift to a debug mode capable of analyzing the semiconductor memory device.

Preferably the debug mode control circuit generates the debug mode activation signal in response to a level of the input voltage received at a single terminal unused by the system in the normal operation.

Preferably, the debug mode is formed of a plurality of modes, there are included at least two the terminal unused by the system in the normal operation, the input voltage is impressed to a first terminal of terminal unused by the system in the normal operation, and a second terminal of terminal unused by the system in the normal operation distinguished from the first terminal receives a mode select signal provided for selecting the plurality of modes.

Preferably, the second terminal is a single terminal, the first terminal has the input voltage impressed thereto and also receives a clock signal, and the debug mode control circuit includes at least one shift register, and changes an internal state in response to the clock signal input to the first terminal, and generates the debug mode activation signal in accordance with a combination of the internal state and the mode select signal input to the second terminal.

Thus the present semiconductor memory device can operate on a system to effect a failure analysis using a no-connection (NC) pin unused by the system in the normal mode of operation. The present semiconductor memory device thus allows various test modes (hereinafter referred to as a debug mode to distinguish it from conventional test mode) to be effected without affecting the system in operation. It can thus conduct a failure acceleration test and specifically analyze phenomena of failure with the system in operation.

Furthermore the present semiconductor device allows a large number of debug modes to be selected through two pins unused by the system. It thus no longer depends on the number of NC pins to provide a large number of debug modes and it can thus provide a variety of debugging.

The foregoing and other objects, features, aspects and advantages of the present invention will become more apparent from the following detailed description of the present invention when taken in conjunction with the accompanying drawings.

### BRIEF DESCRIPTION OF THE DRAWINGS

In the drawings:

FIG. 1 is a functional block diagram for functionally illustrating a semiconductor device of the present invention in a first embodiment;

FIG. 2 is a circuit diagram showing a configuration of a debug mode control circuit in the FIG. 1 device;

FIG. 3 is a circuit diagram showing a configuration of a reference voltage generation circuit in the FIG. 1 device;

FIG. 4 is a circuit diagram partially showing a configuration of a data input/output circuit in the FIG. 1 device;

FIG. 5 schematically shows a configuration of a semiconductor module with the FIG. 1 device mounted thereon;

FIG. 6 is a functional block diagram functionally illustrating the semiconductor device of the present invention in a third embodiment;

FIG. 7 is a circuit diagram showing a configuration of a debug mode control circuit in the FIG. 6 device;

FIG. 8 is a functional block diagram functionally illustrating the semiconductor device of the present invention in a fourth embodiment;

FIG. 9 is a circuit diagram showing a configuration of a debug mode control circuit in the FIG. 8 device;

FIG. 10 is a circuit diagram showing a configuration of an internal signal monitor circuit in the FIG. 8 device;

FIG. 11 is a functional block diagram functionally illustrating the semiconductor device of the present invention in a fifth embodiment;

FIG. 12 is a circuit diagram showing a configuration of a signal history record and output circuit in the FIG. 11 device;

FIG. 13 is a circuit diagram showing a configuration of an SR-type flip-flop circuit in the FIG. 12 circuit;

FIG. 14 is a functional block diagram functionally illustrating the semiconductor device of the present invention in a sixth embodiment;

FIG. 15 is a circuit diagram showing a configuration of a debug mode control circuit in the FIG. 14 device;

FIG. 16 is timing plots representing a timing of an operation in the FIG. 15 circuit; and

FIG. 17 is a functional block diagram for functionally illustrating a conventional semiconductor memory device.

### DESCRIPTION OF THE PREFERRED EMBODIMENTS

Hereinafter the embodiments of the present invention will be described specifically with reference to the drawings. In the figures, like components are denoted by like reference characters and their descriptions will thus not be repeated.

First Embodiment

FIG. 1 is a functional block diagram for functionally illustrating a semiconductor device of a first embodiment. As shown in FIG. 1, a semiconductor memory device 100 includes a reference voltage generation circuit 1, an internal voltage generation circuit 2, a data input/output circuit 3, a debug mode control circuit 4, an address decode circuit 8, and an internal control circuit 9.

Reference voltage generation circuit 1 generates a reference voltage Vref serving as a reference for an internal power supply voltage generated by internal voltage generation circuit 2 and outputs reference voltage Vref to internal voltage generation circuit 2. When debug mode control circuit 4 outputs a debug mode signal/TM having a low level, reference voltage generation circuit 201 outputs to internal voltage generation circuit 2 reference voltage Vref having a voltage level of an external power supply voltage, which is higher than an internal power supply voltage provided in a normal mode of operation.

In accordance with reference voltage Vref received from reference voltage generation circuit 1 internal voltage generation circuit 2 converts the external power supply voltage to an internal power supply voltage and outputs it to each circuit internal to semiconductor memory device 100. In semiconductor memory device 100, when the debug mode is active, internal voltage generation circuit 2 generates the internal power supply voltage based on reference voltage Vref having a higher voltage level than in the normal mode of operation and a test accelerating a marginal failure is thus conducted.

Data input/output circuit 3 is a buffer circuit allowing external data communication. When debug mode control circuit 4 outputs debug mode signal/TM having the low level, data input/output circuit 3 in outputting data operates to provide a smaller amount of electric current to data input/output pins DQ0-DQm than in the normal mode of operation to reduce an ability to drive externally outputting internal data. Thus, in semiconductor memory device 100, when the debug mode is active, a test is acceleratively conducted for data input/output circuit 3 for a marginal failure.

Debug mode control circuit 4 switches debug mode signal/TM in logical level in accordance with a voltage impressed to an NC pin 1 unused by the system in the normal mode of operation and outputs the signal to reference voltage generation circuit 1 and data input/output circuit 3. When NC pin 1 has been impressed thereto a voltage having no less than a predetermined voltage level higher than the external power supply voltage, debug mode control circuit 4 determines that the debug mode is entered and debug mode control circuit 4 outputs debug mode signal/TM of the low level. When NC pin 1 does not have the external power supply voltage impressed thereto or it has been impressed thereto a voltage lower than the predetermined level of voltage, debug mode control circuit 4 determines that the normal mode of operation is entered and debug mode control circuit 4 outputs debug mode signal/TM of the high level.

Address decode circuit 8 latches externally received address signals A0-An and internally outputs an address signal.

Internal control circuit 9 is a circuit controlling each internal circuit in response to externally received control signals/CS, /RAS, /CAS and /WE.

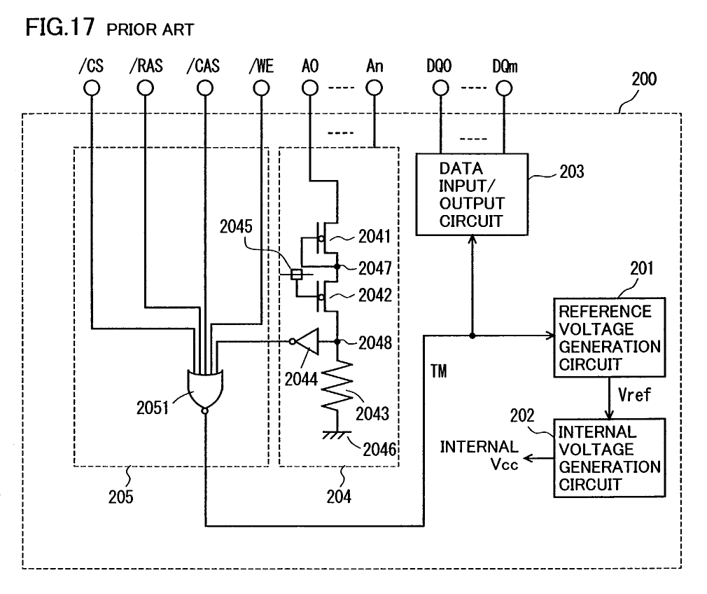

Note that although address decode circuit 8 and internal control circuit 9, as provided in the first embodiment and the second to sixth embodiments described hereinafter, have no direct relationship with the debug mode, they are shown to compare them with the conventional example shown in FIG. 17.

In semiconductor memory device 100 when NC pin 1 has been impressed thereto a predetermined voltage higher than the external power supply voltage debug mode control circuit 4 determines that the debug mode is entered and debug mode control circuit 4 outputs debug mode signal/TM of the low level to reference voltage generation circuit 1 and data input/output circuit 3.

When debug mode signal/TM has the low level, reference voltage generation circuit 1 outputs reference voltage Vref to internal voltage generation circuit 2 at the voltage level of the external power supply voltage, which is higher than the level of Vref provided in the normal mode of operation. In accordance with reference voltage Vref received from reference voltage generation circuit 1, internal voltage generation circuit 2 generates an internal power supply voltage having the external power supply voltage level and outputs it to each circuit.

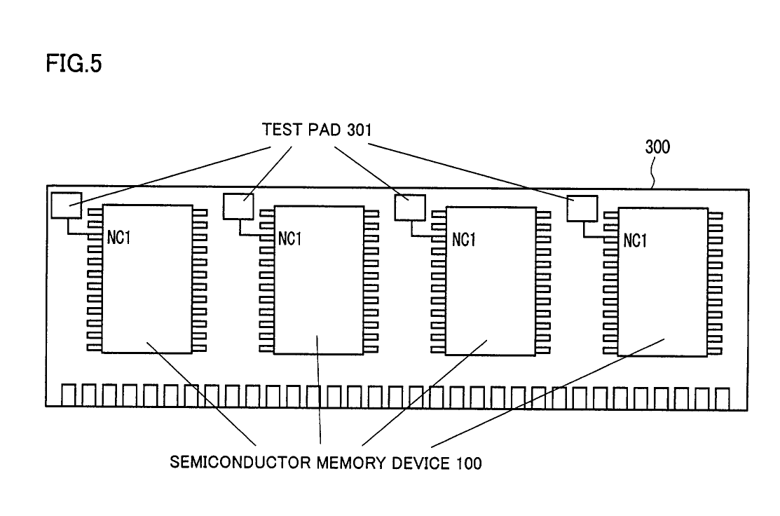

When debug mode signal/TM received from debug mode control circuit 4 has the low level, data input/output circuit 3 in outputting data operates to allow an output circuit to have a smaller ability to drive outputting internal data to data input/output pin DQ0-DQm than in the normal mode of operation. More specifically, as will be described hereinafter with reference to FIG. 4, it operates to drive a smaller number of transistors to output the internal data to data input/output pin DQ0-DQm than in the normal mode of operation so as to reduce the driving ability.

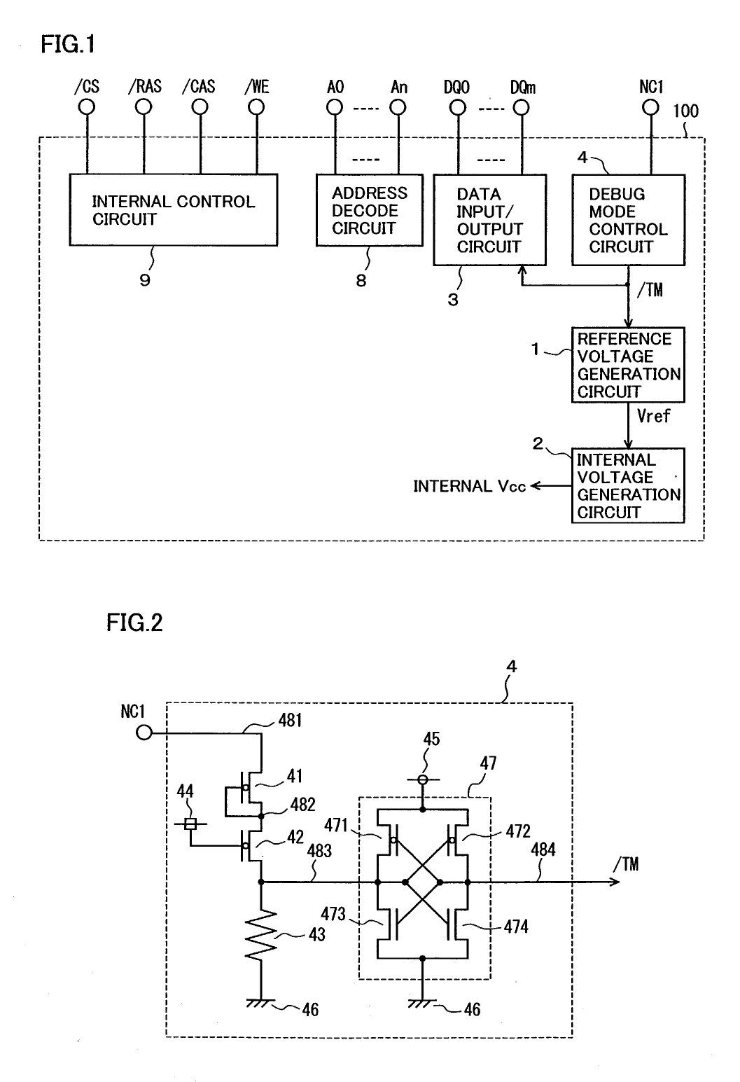

FIGS. 2-4 show debug mode control circuit 4, reference voltage generation circuit 1 and data input/output circuit 3, respectively, in circuit configuration. Note that internal voltage generation circuit 2 will not particularly be described as it is referred to as a typical voltage conversion circuit (a voltage down converter (VDC)) referring to reference voltage Vref convert an external power supply voltage to an internal power supply voltage and output it to each internal circuit.

FIG. 2 is a circuit diagram showing a configuration of debug mode control circuit 4. As shown in the figure, debug mode control circuit 4 includes p-channel MOS transistors 41, 42, a resistor 43, external power supply nodes 44, 45, a ground node 46, a bistable latch circuit 47, and nodes 481-484. Bistable latch circuit 47 is formed of p-channel MOS transistors 471, 472 and n-channel MOS transistors 473, 474.

P-channel MOS transistor 41 is diode-connected and has its source connected through node 481 to NC pin 1. P-channel MOS transistor 42 has its source, drain and gate connected to p-channel MOS transistor 41 at the drain, resistor 43 and external power supply node 44, respectively. Node 483 connects p-channel MOS transistor 42, resistor 43 and bistable latch circuit 47 together. Bistable latch circuit 47 latches a signal appearing on node 483 and outputs to node 484 the signal that is inverted in logical level.

In debug mode control circuit 4, when NC pin 1 has been impressed thereto a voltage of no less than external power supply voltage ext.Vcc plus 2VT, node 483 attains a logical high level, wherein VT represents a threshold voltage of p-channel MOS transistors 41, 42, since when node 482 has a voltage VO and NC pin 1 has a voltage VA0 impressed thereto, then turning p-channel MOS transistors 41, 42 on entails V0−VA0≦−VT and ext.Vcc−V0≦−VT and from these two expressions entails VA0≧ext.Vcc+2VT.

Thus when NC pin 1 has the voltage no less than external power supply voltage ext. Vcc plus 2VT impressed thereto the output node or node 484, with bistable latch circuit 47 operating to invert the logical level of node 483, attains the low level. Thus debug mode signal/TM of the low level is output. When NC pin 1 does not have a voltage impressed thereto or it does not have no less than external power supply voltage ext.Vcc plus 2VT impressed thereto, debug mode signal/TM of the high level is output.

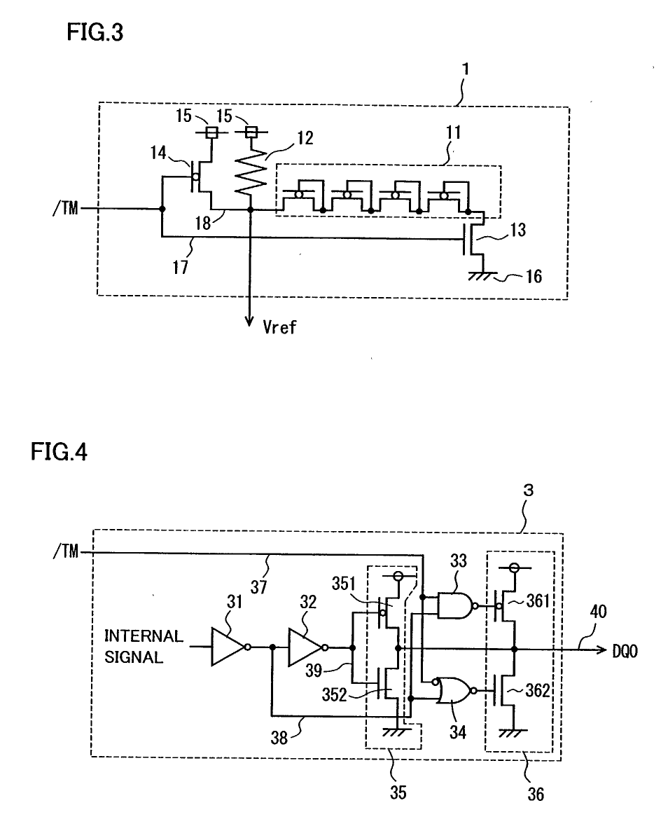

FIG. 3 is a circuit diagram showing a configuration of reference voltage generation circuit 1. As shown in the figure, reference voltage generation circuit 1 includes a group 11 of diode-connected, p-channel MOS transistors connected in series, a resistor 12, an n-channel MOS transistor 13, a p-channel MOS transistor 14, an external power supply node 15, a ground node 16, and nodes 17, 18.

N and p-channel MOS transistors 13 and 14 have their respective gates receiving debug mode signal/TM. P-channel MOS transistor 14 and resistor 12 are connected between external power supply node 15 and node 18 in parallel. The group 11 of p-channel MOS transistors has one terminal connected to node 18 and the other terminal connected to n-channel MOS transistor 13. The node 18 voltage is output as reference voltage Vref to internal voltage generation circuit 2.

Herein when the debug mode is not active and debug mode signal/TM has the high level then p- and n-channel MOS transistors 14 and 13 turn off and on, respectively. Thus resistor 12, the group 11 of p-channel MOS transistors and n-channel MOS transistor 13 pass a leak current and a voltage determined by resistor 12 appears at node 18. This voltage of node 18, or reference voltage Vref, is lower than the external power supply voltage on external power supply node 15 by an amount down-converted by resistor 12.

When the debug mode is active and debug mode signal/TM has the low level then p- and n-channel MOS transistors 14 and 13 turn on and off, respectively. Thus at node 18 there appears an external power supply voltage through p-channel MOS transistor 14 and reference voltage Vref is thus the external power supply voltage.

FIG. 4 is a circuit diagram showing a configuration of data input/output circuit 3. FIG. 4 shows a configuration related to outputting data at data input/output pin DQ0. The other data input/output pins are similarly configured and will thus not be shown or described. Furthermore, a well known input circuit is used to externally input data and its circuit configuration will thus not particularly be described.

With reference to FIG. 4, data input/output circuit 3 includes inverters 31, 32, an NAND gate 33, an NOR gate 34, drive circuits 35, 36, and nodes 37-40. Drive circuit 35 includes p- and n-channel MOS transistors 351 and 352. Drive circuit 36 includes p- and n-channel MOS transistors 361 and 362.

Whether or not debug mode signal/TM activates the debug mode, drive circuit 35 operates in response to internal data IDQ0 of a logical level input to inverter 31 to output to node 40 the data output to data input/output pin DQ0. More specifically, when internal data IDQ0 has the high level, inverter 32 provides an output of the high level and p- and n-channel MOS transistors 351 and 352 thus turn off and on, respectively. Node 40 thus attains the low level.

By contrast, when internal data IDQ0 has the low level, inverter 32 provides an output of the low level and p- and n-channel MOS transistors 351 and 352 thus turn on and off, respectively. Node 40 thus attains the high level.

Drive circuit 36 provides different operations depending on whether debug mode signal/TM activates the debug mode. When debug mode signal/TM has the high level or the debug mode is not active, NAND and NOR gates 33 and 34 each output an inverted version of the logical level of node 38. More specifically, NAND and NOR gates 33 and 34 output their respective logical levels determined by the logical level of internal data IDQ0 input to inverter 31 and when internal data IDQ0 has the high level NAND and NOR gates 33 and 44 both output the high level. P- and n-channel MOS transistors 361 and 362 are thus turned off and on, respectively. Node 40 is thus driven to the low level.

By contrast, when internal data IDQ0 has the low level NAND and NOR gates 33 and 34 both output the low level. P- and n-channel MOS transistors 361 and 362 are thus turned on and off, respectively. Node 40 is thus driven to the high level.

Furthermore, when the debug mode signal/TM has the low level or the debug mode is active, drive circuit 36 has NAND and NOR gates 33 and 34 outputting the high and low levels, respectively, whatever logical level internal data IDQ0 may have. P- and n-channel MOS transistors 361 and 362 are thus both turned off. Drive circuit 36 thus does not drive node 40 to the high or low level.

Thus data input/output circuit 3 in the normal mode of operation uses the both of drive circuits 35 and 36 to output data to data input/output pin DQ0. By contrast, data input/output circuit 3 in the debug mode of operation uses only drive circuit 35 to output data to data input/output pin DQ0.

Thus in the first embodiment semiconductor memory device 100 can operate on a system to effect a failure analysis using an NC pin unused by the system in the normal mode of operation. The present device thus can increase an internal power supply voltage to conduct a test accelerating a failure to occur and a test accelerating a failure in driving of data input/output circuit 3 without affecting the system in operation. It can thus specifically analyze phenomena of failure with the system in operation.

Second Embodiment

In the second embodiment, more than one semiconductor memory device 100 described in the first embodiment are mounted on a semiconductor module and thus used. FIG. 5 schematically shows a semiconductor module with semiconductor memory devices 100 mounted thereon. As shown in the figure, a semiconductor module 300 includes a plurality of semiconductor memory devices 100 and a plurality of test pads 301 provided to semiconductor memory devices 100, respectively.

Each test pad 301 is connected to the corresponding semiconductor memory device 100 at NC pin 1. The predetermined voltage described in the first embodiment is impressed to test pad 301 to activate a debug mode. Typically when a semiconductor memory device is mounted on a system an NC pin is often connected to a power supply line or a ground line. In the second embodiment test pad 301 connected to NC pin 1 has a predetermined voltage impressed thereto to operate a debug mode with the system in operation and accordingly test pad 301 and NC pin 1 are floated.

Thus in the second embodiment semiconductor memory devices 100 mounted on semiconductor module 300 are each provided with test pad 301. Thus on semiconductor module 300 semiconductor memory devices 100 can individually be set in a debug mode to provide enhanced degree of freedom in testing the same.

Third Embodiment

In a third embodiment a semiconductor device can use a plurality of NC pins unused by the system and thus selectively conduct a failure acceleration test increasing an internal power supply voltage, as has been described in the first embodiment, and a test accelerating a failure of a data input/output circuit in driving.

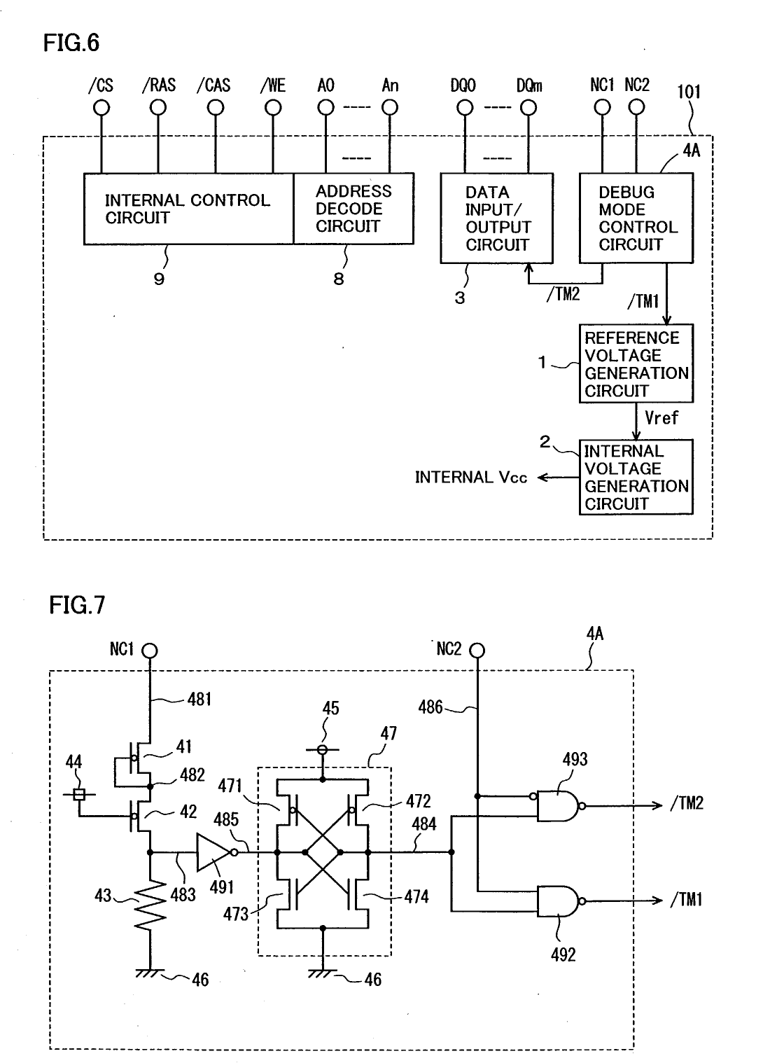

FIG. 6 is a functional block diagram for functionally illustrating a semiconductor memory device of the third embodiment. As shown in the figure, semiconductor memory device 101 includes a reference voltage generation circuit 1, an internal voltage generation circuit 2, a data input/output circuit 3, a debug mode control circuit 4A, an address decode circuit 8, and an internal control circuit 9.

Circuits 1, 2, 3, 8 and 9 are identical in configuration to those described in the first embodiment. In the third embodiment reference voltage generation circuit 1 receives a debug mode signal/TM1, rather than debug mode signal/TM of the first embodiment, from debug mode control circuit 4A. Furthermore in the third embodiment data input/output circuit 3 receives a debug mode signal/TM2, rather than debug mode signal/TM of the first embodiment, from debug mode control circuit 4A.

Debug mode control circuit 4A operates in accordance with a voltage impressed to NC pins 1 and 2 unused in the normal mode operation by the system, to switch debug mode signals/TM1 and /TM2 in logical level and output debug mode signals/TM1 and /TM2 to reference voltage generation circuit 1 and data input/output circuit 3, respectively. When NC pin 1 has been impressed thereto a voltage no less than a predetermined voltage level higher than an external power supply voltage, debug mode control circuit 4A determines that a debug mode is activated. Debug mode control circuit 4A then operates in response to a signal in logical level input to NC pin 2 to output either debug mode signal/TM1 or /TM2 having the low level.

When NC pin 1 does not have a voltage impressed thereto or it has been impressed thereto a voltage less than the predetermined voltage level, debug mode control circuit 4A determines that the normal mode of operation is activated and debug mode control circuit 4A outputs debug mode signals/TM1 and /TM2 both having the high level.

In semiconductor memory device 101, as well as in semiconductor memory device 101 of the first embodiment, when NC pin 1 has external power supply voltage ext. Vcc plus 2VT or more impressed thereto, debug mode control circuit 4A determines that the debug mode is active, and when NC pin 2 has also a voltage impressed thereto, then debug mode control circuit 4A outputs debug mode signals/TM1 and /TM2 having the low and high levels, respectively, to increase a level of internal power supply voltage to activate a mode of test accelerating a failure to occur.

When NC pin 2 does not have a voltage impressed thereto, then debug mode control circuit 4A outputs debug mode signals/TM1 and /TM2 having the high and low levels, respectively, to activate a mode of test accelerating a failure of data input/output circuit 3 in driving.

FIG. 7 is a circuit diagram showing a configuration of debug mode control circuit 4A. As shown in the figure, debug mode control circuit 4A corresponds to the FIG. 2 debug mode control circuit 4 plus an inverter 491, NAND gates 492, 493, and nodes 485, 486. Node 486 is connected to NC pin 2.

The circuit configuration from NC pin 1 through node 483 is identical to that of debug mode control circuit 4 described in the first embodiment. Thus in debug mode control circuit 4A, when NC pin 1 has external power supply voltage ext. Vcc plus 2VT or more in voltage impressed thereto, node 483 attains the high level and node 485 has a logical level inverted by inverter 491 to attain the low level. Thus, node 484, with bistable latch circuit 47 operating to invert the logical level of node 485, attains the high level. When NC pin 1 has a voltage less than external power supply voltage ext. Vcc plus 2VT impressed thereto then node 484 attains the low level.

Herein when NC pin 1 has a voltage less than external power supply voltage ext. Vcc plus 2VT impressed thereto and node 484 has the low level, then NAND gates 492 and 493 both output the high level, whatever logical level node 486 may have that depends on the voltage input to NC pin 2. Thus debug mode signals/TM1 and /TM2 output both have the high level and the debug mode is thus not activated.

When NC pin 1 has external power supply voltage ext. Vcc plus 2VT or more impressed thereto and node 484 has the high level, NAND gates 492 and 493 provide their respective outputs determined by whether NC pin 2 has a voltage impressed thereto. More specifically, when NC pin 2 has a voltage impressed thereto, NAND gates 492 and 493 output the low and high levels, respectively. Thus reference voltage generation circuit 1 is activated in the debug mode and data input/output circuit 3 normally operates.

When NC pin 2 does not have a voltage impressed thereto, NAND gates 492 and 493 output the high and low levels, respectively. Thus data inputs/output circuit 3 is activated in the debug mode and reference voltage generation circuit 1 normally operates.

Thus in semiconductor memory device 101 of the third embodiment, when a voltage impressed to NC pin 1 allows the debug mode to be activated, a voltage impressed to NC pin 2 allows an internal power supply voltage to be increased in level to selectively conduct a test accelerating a failure to occur and a test accelerating a failure of a data input/output circuit in driving.

Fourth Embodiment

In a fourth embodiment, in addition to the two debug modes conducting with the system in operation the test increasing an internal power supply voltage in level to accelerate a failure to occur and the test accelerating a failure of data input/output circuit 3 in driving, there is further provided a debug mode capable of monitoring a preset, any internal signal.

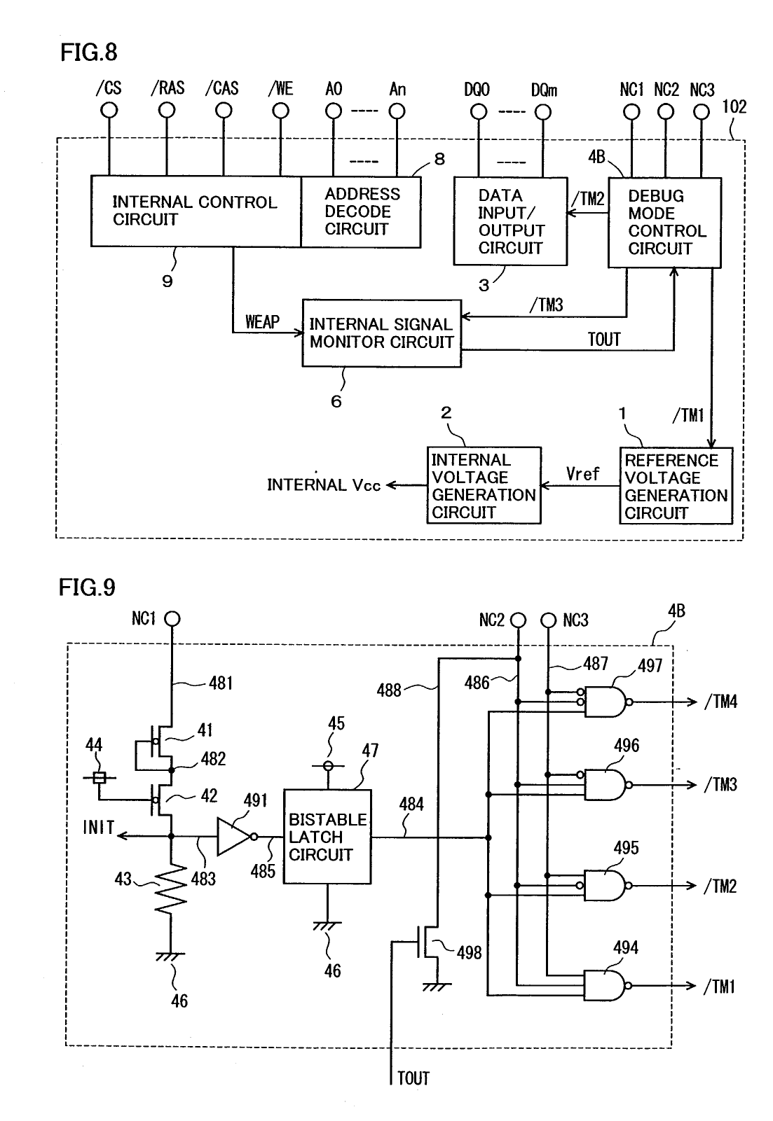

FIG. 8 is a functional block diagram for functionally illustrating a semiconductor memory device of the fourth embodiment. As shown in the figure, a semiconductor memory device 102 includes a reference voltage generation circuit 1, an internal voltage generation circuit 2, a data input/output circuit 3, a debug mode control circuit 4B, an internal control circuit 5, an internal signal monitor circuit 6, an address decode circuit 8, and an internal control circuit 9.

Circuits 1, 2, 3, 8 and 9 are the same as those described in the first or third embodiment.

Debug mode control circuit 4B operates in accordance with an input voltage impressed to NC pins 1-3 unused in the normal mode operation by the system, to switch debug mode signals/TM1 to /TM3 in logical level to output debug mode signals/TM1 to /TM3 to circuits 1, 3 and 6, respectively.

When NC pin 1 has been impressed thereto a voltage having a predetermined voltage level higher than the external power supply voltage, debug mode control circuit 4B determines that the debug mode is active. Debug mode control circuit 4B then operates in response to a signal in logical level input to NC pins 2 and 3 to output one of debug mode signals/TMl to /TM3 having the low level. When NC pin 1 does not have a voltage impressed thereto or it has been impressed thereto a voltage lower than the predetermined voltage level, then debug mode control circuit 4B determines that the normal mode of operation is active and debug mode control circuit 4B outputs debug mode signals/TM1 to /TM3 all having the high level.

Furthermore debug mode control circuit 4B receives from internal signal monitor circuit 6 a signal TOUT representative of an internal signal in status monitored by internal signal monitor circuit 6.

Internal control circuit 9 outputs an internal signal WEAP produced by appropriately combining control signals/CS, /RAS, /CAS and /WE together. In the fourth embodiment internal signal WEAP is monitored by internal signal monitor circuit 6. Herein internal signal monitor circuit 6 may monitor any type of internal signal and the function of internal signal WEAP is not an issue in the following description and internal signal WEAP itself will thus not be described hereinafter.

When internal signal monitor circuit 6 receives debug mode signal/TM3 having the low level from debug mode control circuit 4B, internal signal monitor circuit 6 is activated to monitor internal signal WEAP in status and output it as output signal TOUT to debug mode control circuit 4B.

In semiconductor memory device 102, as well as in the previously described semiconductor memory devices 100, 101, when NC pin 1 has a voltage of no less than external power supply voltage ext. Vcc plus 2VT impressed thereto, debug mode control circuit 4B determines that the debug mode is active and when NC pins 2 and 3 both also have voltage impressed thereto, then debug mode control circuit 4B outputs debug mode signal/TM1 having the low level and debug mode signals/TM2 and /TM3 having the high level, to activate a test increasing an internal power supply voltage in level to accelerate a failure to occur.

Furthermore, when NC pin 2 does not have a voltage impressed thereto and NC pin 3 has a voltage impressed thereto, then debug mode control circuit 4B outputs debug mode signal/TM2 having the low level and debug mode signals/TM1 and /TM3 having the high level to activate a test accelerating a failure of data input/output circuit 3 in driving.

Furthermore, when NC pin 2 has a voltage impressed thereto and NC pin 3 does not have a voltage impressed thereto, then debug mode control circuit 4B outputs debug mode signal/TM3 having the low level and debug mode signals/TM1 and /TM2 having the high level to activate internal signal monitor circuit 6.

Then when debug mode control circuit 4B receives signal TOUT having the high level from internal signal monitor circuit 6, debug mode control circuit 4B grounds a node connected to NC pin 2. NC pin 2 can thus vary in voltage and externally detecting this variation allows variation in internal signal WEAP to be detected.

FIG. 9 is a circuit diagram showing a configuration of debug mode control circuit 4B. As shown in the figure, debug mode control circuit 4B corresponds to the FIG. 7 circuit 4A with NAND gates 492 and 493 replaced by four 3-input NAND gates 494-497, an n-channel MOS transistor 498 and nodes 487, 488. Node 487 is connected to NC pin 3.

The circuit configuration form NC pin 1 through node 484 is identical to that of debug mode control circuit 4A described in the second embodiment. Thus in debug mode control circuit 4B, when NC pin 1 has external power supply voltage ext. Vcc plus 2VT or more in voltage impressed thereto, node 484 attains the high level and otherwise node 484 attains the low level.

Herein when NC pin 1 has a voltage smaller than external power supply voltage ext. Vcc plus 2VT impressed thereto and node 484 has the low level, NAND gates 494-497 all output the high level, whatever logical level of a signal NC pins 2 and 3 may receive. Thus debug mode signals/TM1 to /TM4 output are all have the high level and the debug mode is thus not activated. Note that although the figure indicates debug mode signal/TM4, this signal is not used in the fourth embodiment and it is a spare signal (this signal is used in a fifth embodiment described hereinafter).

When NC pin 1 has a voltage equal to or greater than external power supply voltage ext. Vcc plus 2VT impressed thereto and node 484 has the high level, then NAND gates 494-497 provide an output determined by a combination of signals input to NC pins 2 and 3. More specifically, when NC pins 2 and 3 both receive a signal having the high level, debug mode signal/TM1 attains the low level and the other debug mode signals/TM2 to /TM4 all attain the high level.

When NC pins 2 and 3 receive their respective signals of the low and high levels, respectively, debug mode signal/TM2 attains the low level and the other debug mode signals/TM1, /TM3, /TM4 all attains the high level.

When NC pins 2 and 3 receives their respective signals having the high and low levels, respectively, debug mode signal/TM3 attains the low level and the other debug mode signals/TM1, /TM3, /TM4 all attain the high level.

Furthermore, when NC pins 2 and 3 receive their respective signals having the low level, debug mode signal/TM4 attains the low level and the other debug mode signals/TM1 to /TM3 all attain the high level.

Node 486 connected to NC pin 2 is connected an n-channel MOS transistor 498 having its source connected to a ground node and having its gate receiving signal TOUT received from internal signal monitor circuit 6. N-channel MOS transistor 498 turns on in response to signal TOUT having the high level and node 488 is grounded. The voltage on node 486 thus varies and externally detecting this variation at NC pin 2 allows an internal signal to be monitored in status.

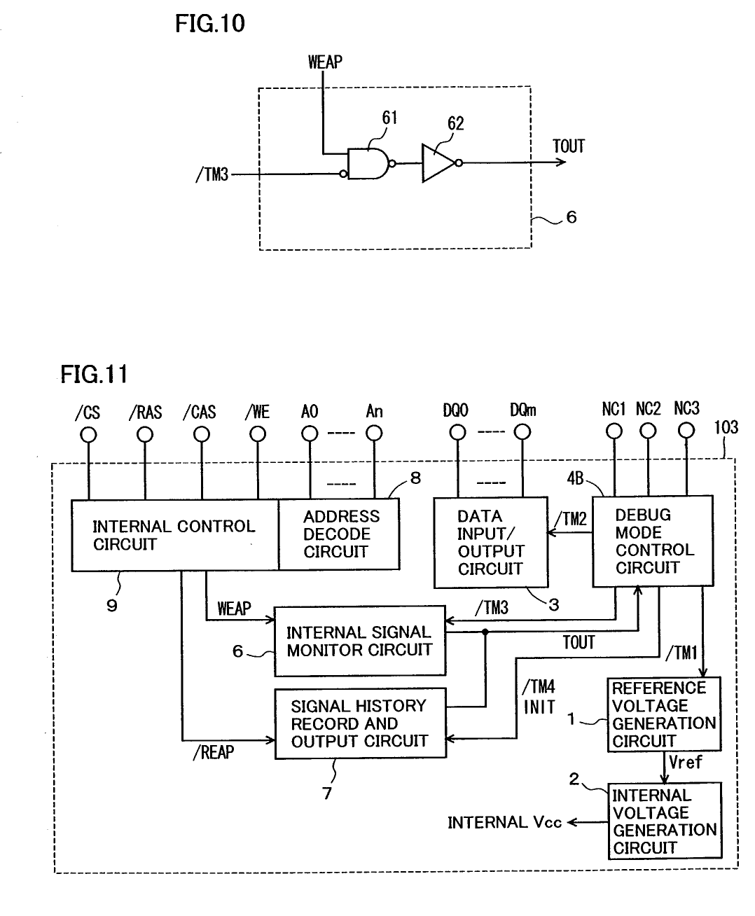

FIG. 10 is a circuit diagram showing a configuration of internal signal monitor circuit 6. As shown in the figure, internal signal monitor circuit 6 includes an NAND gate 61 and an inverter 62.

NAND gate 61 receives an inverted version of test mode signal/TM3 and signal WEAP to be monitored.

Inverter 62 inverts an output received from NAND gate 61 and outputs signal TOUT to debug mode control circuit 4B.

Internal signal monitor circuit 6 is activated in response to debug mode signal/TM3 having the low level. More specifically, when debug mode signal/TM3 has the low level, NAND gate 61 operates in response to a logical level of monitored signal WEAP to invert the logical level and output the level, which is further inverted by inverter 62 to output signal TOUT.

Thus when debug mode signal/TM3 has the low level and internal signal monitor circuit 6 is activated, signal WEAP has its status represented in signal TOUT and thus output.

Thus in semiconductor memory device 102 of the fourth embodiment, at least three NC pins unused by the system can be used to select at least four debug modes, and thus in addition to the two debug modes described in the first and third embodiments, an additional debug mode can also be provided to monitor an internal signal.

Furthermore in semiconductor memory device 102, a debug mode can be operated to monitor an internal signal with the system in operation, and the internal signal can thus be monitored in status with the system in operation to capture an instant at which a failure occurs and this can significantly contribute to failure analysis.

Fifth Embodiment

A fifth embodiment further provides a debug mode capable of recording and outputting a history of any present internal signal in addition to the three debug modes described in the first, third and fourth embodiments.

For example, it is possible that a problem introduced in a system is attributed to an invalid command or a new command having been input that has not conventionally been used. In this case, the cause of the problem can hardly be determined from speculation, since there are a large number of possible inputs causing the problem. In the fifth embodiment a semiconductor memory device is capable of recording and outputting a variation introduced in an internal signal, and it in effect includes more than one circuit recording an internal signal to simultaneously record variation introduced in a plurality of internal signals. The semiconductor memory device operates until an error is introduced on the system, and once an error has been introduced all of the recording circuits have their contents checked to determine a suspect input.

When it has been found that there exists a suspect input, internal signal monitor circuit 6 described in the fourth embodiment waits for the input of interest to occur, and when the input of interest is detected, such notification is externally provided and used for example as a trigger for a logic analyzer to analyze system failure.

FIG. 11 is a functional block diagram for functionally illustrating the semiconductor memory device of the fifth embodiment As shown in the figure, a semiconductor memory device 103 includes a reference voltage generation circuit 1, an internal voltage generation circuit 2, a data input/output circuit 3, a debug mode control circuit 4B, an internal control circuit 5, an internal signal monitor circuit 6, a signal history record and output circuit 7, an address decode circuit 8, and an internal control circuit 9.

Circuits 1, 2, 3, 4B, 5, 6, 8 and 9 are identical to those described in the first, second or fourth embodiment.

Debug mode control circuit 4B outputs to signal history record and output circuit 7 a debug mode signal/TM4 and a signal INIT appearing at node 483 shown in FIG. 9.

Internal control circuit 5 outputs an internal signal/REAP produced by appropriately combining externally received control signals together. In the fifth embodiment, internal signal/REAP is recorded and stored by signal history record and output circuit 7. Herein the function of the exact internal signal/REAP provided as a subject will not be described for the same reason as described in the fourth embodiment for signal WEAP.

Signal history record and output circuit 7 is activated in response to debug mode signal/TM4 received from debug mode control circuit 4B and having the low level to record a history in variation of internal signal/REAP and output an output signal TOUT to debug mode control circuit 4B. Furthermore signal history record and output circuit 7 receives signal INIT from debug mode control circuit 4B for initializing an internal state and it is initialized in response to signal INIT having the high level.

In semiconductor memory device 103, as well as in semiconductor memory devices 100-102 described above, when NC pin 1 has external power supply voltage ext. Vcc plus 2VT or more impressed thereto, debug mode control circuit 4B determines that a debug mode is active and when neither NC pins 2 nor 3 also receive a signal, then debug mode control circuit 4B outputs debug mode signal/TM4 having the low level and debug mode signals/TM1 to /TM3 having the high level, to activate signal history record and output circuit 7.

Other combinations of signals input to NC pins 2 and 3 allow a debug mode to have statuses, as has been described in the fourth embodiment.

Furthermore when NC pin 1 has external power supply voltage ext. Vcc plus 2VT or more impressed thereto, debug mode control circuit 4B outputs signal INIT having the high level to signal history record and output circuit 7. In response to signal INIT having the high level, signal history record and output circuit 7 initializes an internal state. After the initialization, signal history record and output circuit 7 records variation introduced in internal signal/REAP and outputs the record of the variation in signal TOUT to debug mode control circuit 4B.

Signal history record and output circuit 7 outputs signal TOUT on a node, which is connected to a node outputting signal TOUT from internal signal monitor circuit 6 and it is thus connected to debug mode control circuit 4B.

Then, as described in the fourth embodiment, when debug mode control circuit 4B has received signal TOUT of the high level from signal history record and output circuit 7, debug mode control circuit 4B grounds a node connected to NC pin 2. NC pin 2 thus varies in voltage and externally detecting this variation allows the history of internal signal/REAP to be detected.

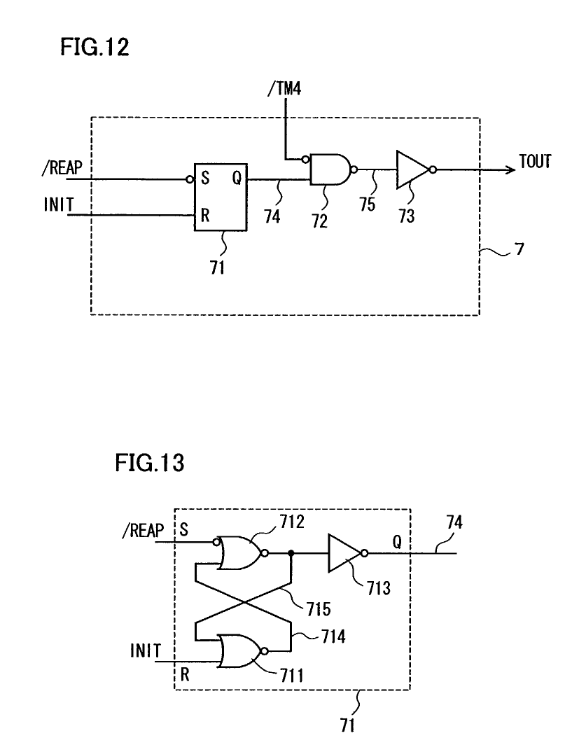

FIG. 12 is a circuit diagram showing a configuration of signal history record and output circuit 7. As shown in the figure, signal history record and output circuit 7 includes an SR-type flip-flop circuit 71, an NAND gate 72, an inverter 73, and nodes 74, 75.

SR-type flip-flop circuit 71 has an output terminal Q reset low when a reset terminal R receives signal INIT having the high level. Furthermore, SR-type flip-flop circuit 71 is associated with node 74 set high when a set terminal S receives signal/REAP having the high level.

NAND gate 72 operates in response to debug mode signal/TM4 having the low level to invert in logical level a signal appearing on node 74 and output it. In contrast, NAND gate 72 operates in response to debug mode signal/TM4 having the high level to output a signal of the high level to node 75, whichever logical level a signal on node 74 may have. In other words, signal TOUT corresponds to a logical level of node 75 that is inverted and it is constantly output having the low level.

FIG. 13 is a circuit diagram showing a configuration of SR-type flip-flop circuit 71. As shown in the figure, SR-type flip-flop circuit 71 includes NOR gates 711, 712, an inverter 713, and nodes 714, 715.

In SR-type flip-flop circuit 71 when signal/REAP serving as a set input has the high level and signal INIT serving as a reset input also attains the high level node 714 attains the low level and node 715 attains the high level. Thus on node 74 appears an output signal having a reset state, as node 715 has its logical level inverted to provide the low level.

In this condition when signal/REAP attains the low level node 715 attains the low level and on node 74 appears an output signal having the high level. Furthermore in response to node 75 having attained the low level the NOR gate 711 output or the node 714 logical level attains the high level. Thus in NOR gate 712 its output node 715 is latched low and node 74 is held high until signal INIT is input as a reset signal.

Thus in semiconductor memory device 103 of the fifth embodiment, at least three NC pins unused by the system of interest can be used to select at least four debug modes. Thus in addition to the three debug modes described in the fourth embodiment, an additional debug mode can also be provided to record and output a history of an internal signal.

Furthermore in semiconductor memory device 103 a debug mode can be operated to record and output a history of an internal signal with the system in operation to acquire a history of a variation of the internal signal that is introduced when an abnormality occurs with the system exactly in operation. For example, it can be detected at device level whether any invalid command has externally been input, and a record thereof can externally be output to significantly contribute to analysis of system failure.

Sixth Embodiment

In the fourth and fifth embodiments, providing at least three debug modes and selectively implementing the same entail at least three NC pins unused by the system of interest.

More specifically, in the fourth and fifth embodiments, the number of signals to be monitored in status or history is limited by that of NC pins unused by the system. More specifically, monitoring 2ⁿ signals entails (n+1) NC pins, wherein “+1” represents NC pin 1.

The sixth embodiment provides a semiconductor memory device capable of designating a large number of debug modes with two NC pins unused by the system.

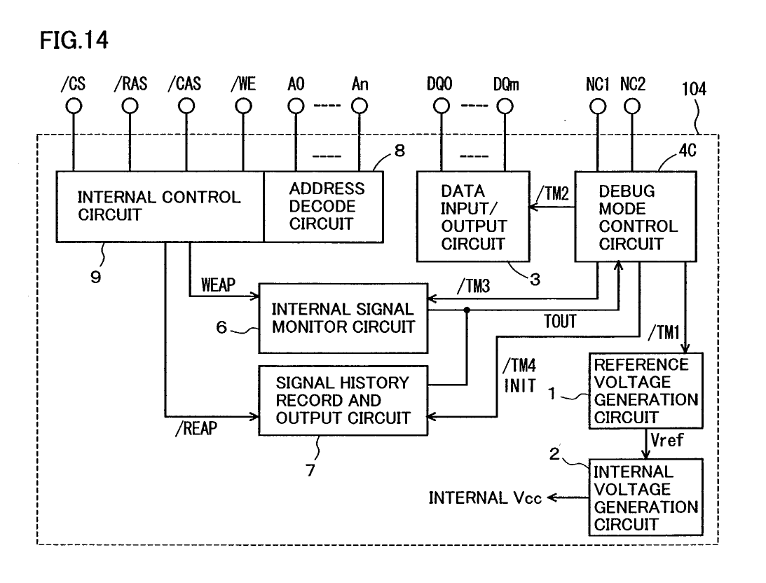

FIG. 14 is a functional block diagram for functionally illustrating the semiconductor memory device of the sixth embodiment. As shown in the figure, a semiconductor memory device 104 corresponds to semiconductor memory device 103 with debug mode control circuit 4B replaced with a debug mode control circuit 4C.

Debug mode control circuit 4C switches debug mode signals/TM1-/TM4 in logical level in accordance with an input voltage impressed to two NC pins 1 and 2 unused in a normal mode of operation by the system of interest, and outputs debug mode signals/TM1-/TM4 to reference voltage generation circuit 1, data input/output circuit 3, internal signal monitor circuit 6 and signal history record and output circuit 7, respectively. When NC pin 1 has been impressed thereto a voltage having at least a predetermined voltage level higher than an external power supply voltage, debug mode control circuit 4C determined that a debug mode is active. Then, when the debug mode is activated, debug mode control circuit 4C outputs one of debug mode signals/TM1-/TM4 of the low level in response to a combination of an internal state transitioning in response to a clock signal input having a voltage level lower than the predetermined voltage level and a status in logical level of a signal input to NC pin 2. A detail description will now be provided hereinafter for an internal operation.

Debug mode control circuit 4C is the same as debug mode control circuit 4B in outputting signal INIT to signal history record and output circuit 7 and receiving signal TOUT from internal signal monitor circuit 6 or signal history record and output circuit 7. Debug mode control circuits 4C operates in response to signal TOUT received from internal signal monitor circuit 6 or signal history record and output circuit 7 and having the high level to ground a node connected to NC pin 2. NC pin 2 thus varies in voltage and externally detecting this variation allows an internal signal to be detected.

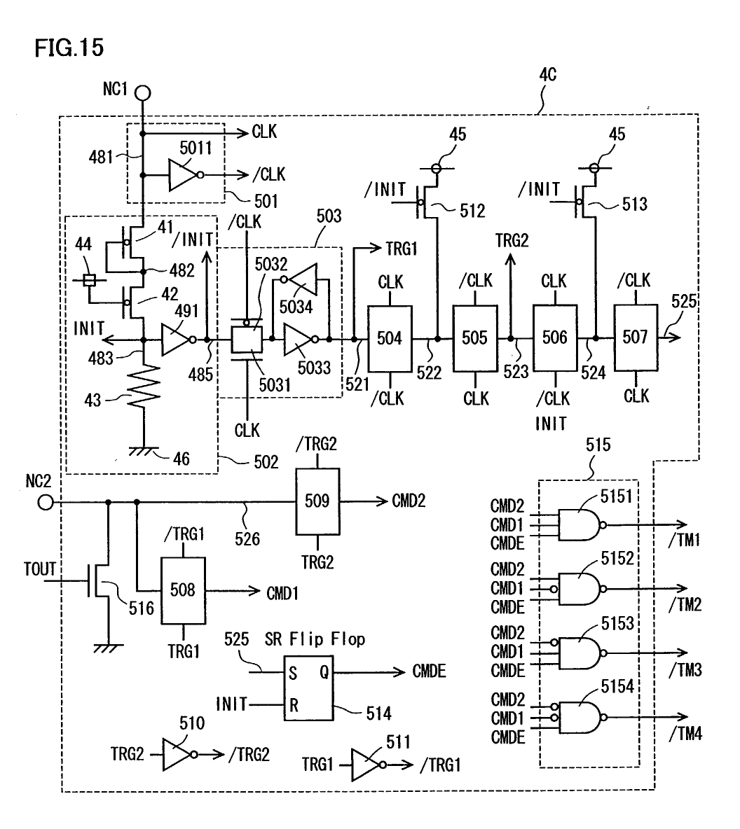

FIG. 15 is a circuit diagram showing a configuration of debug mode control circuit 4C of semiconductor memory device 104. As shown in the figure, debug mode control circuit 4C includes a clock signal generation unit 501, an initialization signal generation unit 502, shift registers 503-509, inverters 510, 511, p-channel MOS transistors 512, 513, an SR-type flip-flop circuit 514, a debug mode signal output unit 515, an n-channel MOS transistor 516, and nodes 521-526.

Clock signal generation unit 501 includes an inverter 5011 and outputs complementary clock signals CLK, /CLK from a clock signal input to NC pin 1.

Initialization signal generation unit 502 has the same circuit configuration as NC pin 1 through node 485 as shown in the FIG. 9 debug mode control circuit 4B. As such in debug mode control circuit 4C, when NC pin 1 has external power supply voltage ext. Vcc plus 2VT or more in voltage impressed thereto, node 483 attains the high level and signal INIT having the high level is output. By contrast when NC pin 1 has less than external power supply voltage ext. Vcc plus 2VT impressed thereto, node 483 attains the low level and signal INIT having the low level is output.

Shift registers 503-509 are synchronized with complementary clock signals CLK, /CLK to invert a received signal and output it. As representatively indicated in the figure at shift register 503, shift registers 503-509 each include an n-channel MOS transistor 5031, a p-channel MOS transistor 5032, and inverters 5033, 5034.

In shift registers 503, 505, 507 n-channel MOS transistor 5031 receives clock signal CLK at its gate and p-channel MOS transistor 5032 receives clock signal/CLK at its gate.

In shift registers 504 and 506 n-channel MOS transistor 5031 receives clock signal/CLK at its gate and p-channel MOS transistor 5032 receives clock signal CLK at its gate.

In shift register 508 n-channel MOS transistor 5031 receives at its gate a signal TRG1 appearing on node 521 and p-channel MOS transistor 5032 receives at its gate a signal/TRG1, i.e., signal TRG1 inverted by inverter 511.

In shift register 509 n-channel MOS transistor 5031 receives at its gate a signal TRG2 appearing on node 523 and p-channel MOS transistor 5032 receives at its gate a signal/TRG2, i.e., signal TRG2 inverted by inverter 510.

Shift registers 503-507 are connected in series and in response to clock signal CLK from shift registers 503 through 507 successively at each shift register a signal is inverted and thus shifted.

Furthermore, shift registers 508 and 509 are connected in parallel with respect to NC pin 2 and output signals CMD1 and CMD2, respectively, corresponding to an output in logical level received by NC pin 2 with their respective signals TRG1 and TRG2 having the high level.

SR-type flip-flop circuit 514 operates in response to signal INIT received at a reset node R to reset low a signal CMDE output from an output node Q, and SR-type flip-flop circuit 514 operates in response to a signal in logical level appearing on node 525 and received at a set node S to set signal CMDE high.

Debug mode signal output unit 515 is a group of 3-input NAND gates receiving signals CMD1 and CMD2, and CMDE. Debug mode signal output unit 515 is activated in response to signal CMDE having the high level and in response to the current combination of signals CMD1 and CMD2 outputs one of debug mode signals/TM1 to /TM4 at the low level.

As has been described in the fifth embodiment for debug mode control circuit 4B, n-channel MOS transistor 516 is connected between node 526 connected to NC pin 2 and a ground node, and has its gate receiving signal TOUT received from internal signal monitor circuit 6 and signal history record and output circuit 7. N-channel MOS transistor 516 turns on in response to signal TOUT having the high level received and node 526 is grounded. Node 526 thus varies in voltage and by detecting this variation at NC pin 2 externally an internal signal can be detected in status.

Note that p-channel MOS transistors 512 and 513 is a circuit provided to initialize nodes 522, 524, and when NC pin 1 has external power supply voltage ext. Vcc plus 2VT or more impressed thereto and nodes 522, 524 are initialized, node 485 has signal/INIT thereon attaining the low level. Thus p-channel MOS transistors 512, 513 turn on and nodes 522, 524 are charged by a power supply node 45 and thus initialized.

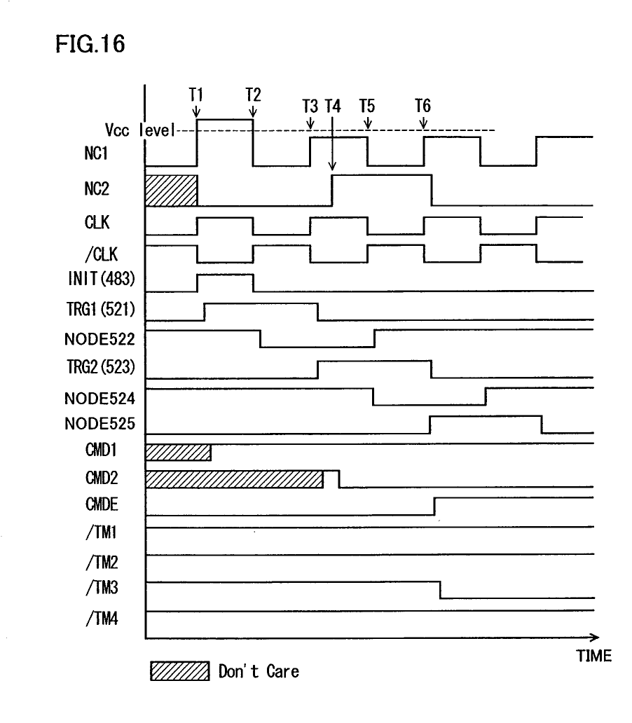

FIG. 16 is timing plots for representing an operation of debug mode control circuit 4C. Hereinafter reference will be made to FIGS. 15 and 16 to describe the operation of debug mode control circuit 4C.

In FIG. 16 at a time T1, when NC pin 1 has external power supply voltage ext. Vcc+2VT or more impressed thereto, responsively clock signal CLK and signal INIT on node 483 attain the high level. Furthermore, with shift register 503 in operation, signal TRGl attains the high level. Shift register 508 is thus put into operation and as such if NC pin 2 receives a signal having the low level then signal CMD1 attains the high level. Furthermore, inverter 491 thus outputs signal/INIT having the low level and p-channel MOS transistors 512, 513 thus turn on and nodes 522, 524 are thus initialized high.

Then in FIG. 16 at a time T2, when NC pin 1 has a voltage dropping in level, signal INIT responsively attains the low level. From the current status of complementary clock signals CLK, /CLK shift register 503 is inoperative and shift register 504 operative and thus signal TRG1 is held to have the high level and node 522 attains the low level.

Then in FIG. 16 at a time T3, NC pin 1 has a voltage less than external power supply voltage ext. Vcc plus 2VT impressed thereto. This inverts clock signals CLK, /CLK, although signal INIT does not goes high and is thus held low. At this timing, shift registers 503, 505 become operative and signals TRG1 and TRG2 attain the low and high levels, respectively, receiving the state of nodes 485, 522 attained prior to time T3. At this time point unless thereafter NC pin 1 has external power supply voltage ext. Vcc plus 2VT or more again impressed thereto and debug mode control circuit 4C is initialized, signal TRG1 is ascertained low and signal CMD1 is accordingly ascertained in status. Furthermore in response to signal TRG2 having attained the high level shift register 509 is operative and in response to NC pin 2 receiving an input of the low level signal CMD2 attains the high level.

Then in FIG. 16 at a time T4, NC pin 2 receives an input having a level going high. In response, with shift register 509 still operative, signal CMD2 attains the low level.

Then in FIG. 16 at a time T5, when NC pin 1 has a voltage dropping in level, shift registers 503, 505 are in response inoperative and shift registers 504, 506 operative. Nodes 522, 524 thus attain the high and low levels, respectively, in response to the state of nodes 521, 523.

Then in FIG. 16 at a time T6, when NC pin 1 has a voltage again rising in voltage with a voltage smaller than external power supply voltage ext. Vcc plus 2VT, shift registers 503, 505, 507 are in response operative, and shift registers 504, 506 inoperative, and signal TRG2 and node 525 attain the low and high levels, respectively, in response to the state of nodes 522, 524. At this time point unless thereafter NC pin 1 has external power supply voltage ext. Vcc plus 2VT or more again impressed thereto and debug mode control circuit 4C is initialized, signal TRG2 is ascertained low and signal CMD2 is accordingly ascertained in status.

Furthermore in response to node 525 driven high, SR-type flip-flop circuit 514 is set and signal CMDE goes high. This activates debug mode signal output unit 515, and in response to the current status of signals CMD1, CMD2, one of debug mode signals/TM1-/TM4 is output having the low level. In the above description at this time point signal CMDl has the high level and signal CMD2 is ascertained low and debug mode signal/TM3 thus attains the low level and is output.

Although not described in detail, debug mode signal/TM1 having the low level is output if NC pin 2 receives an input of the low level in both an interval with signal TRGl having the high level (i.e., in FIG. 16 the interval from time T1 through T3, referred to as an interval 1) and an interval with signal TRG2 having the high level (i.e., in FIG. 16 the interval from time T3 through T6, referred to as an interval 2).

Furthermore when in interval 1 NC pin 2 receives an input transitioning to the high level or having the high level from the outset and in interval 2 NC pin 2 receives an input falling to the low level, then debug mode signal/TM2 having the low level is output.

Furthermore when in interval 1 NC pin 2 receives an input transitioning to the high level or having the high level from the outset and also in interval 2 NC pin 2 receives an input having the high level, then debug mode signal/TM4 having the low level is output.

Thus, synchronized with a clock received by NC pin 1 and driven by an input received by NC pin 2, a large number of select signals can be produced with only two pins and a large number of debug modes can thus be selected.

While four debug modes can be selected in the above description, increased numbers of shift registers allow more than four debug modes to be provided and thus selected.

Thus in semiconductor memory device 104 of the sixth embodiment, two NC pins unused by the system of interest can be used to select a large number of debug modes. Thus without limitations imposed by the number of NC pins a large number of debug modes can be provided and a various types of debugging can thus be effected.

Note that in the third to sixth embodiments, as well as in the second embodiment, a plurality of semiconductor memory devices 101-104 may be mounted on a semiconductor module and each may have each NC pin provided with a test pad individually.

Furthermore in each of the embodiments, when debug mode signal/TM has the low level, reference voltage generation circuit 1 generates reference voltage Vref having a voltage level of an external power supply voltage higher than an internal power supply voltage provided in a normal mode of operation. Alternatively, reference voltage generation circuit 1 may generate reference voltage Vref having a lower voltage level than the internal power supply voltage provided in the normal mode of operation. Reduced internal power supply voltage allows a test to be conducted on a system for a failure in writing to a memory cell serving as a storage element, access failure, and other similar failures.

Furthermore in each of the above embodiments, when debug mode signal/TM has the low level, data input/output circuit 3 operates to provide a smaller amount of drive current than in the normal mode of operation to provide a reduced ability to drive externally outputting internal data. Alternatively, the driving ability may be increased. For example, if input/output circuit 3 normally operates with a driving ability which is not maximum, in order to debug an abnormality introduced in the system, a debug mode is activated and the driving ability is increased, and as a result the abnormality is resolved, such a debug result can be obtained as in the normal mode of operation the driving ability may have been insufficient.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device capable of failure analysis while the semiconductor memory device is in operation, comprising:
a plurality of terminals capable of externally communicating a power supply voltage, data and a signal;
an internal circuit effecting a predetermined operation in response to an externally received signal; and
a debug mode control circuit activated in response to a level of a input voltage received at a terminal unused by said system in a normal operation, to generate and output to said internal circuit a debug mode activation signal enabling the semiconductor memory device in a debug mode, wherein:
said internal circuit is operative in response to said debug mode activation signal to effect said predetermined operation and meanwhile shift to a debug mode capable of analyzing the semiconductor memory device.

2. The semiconductor memory device according to claim 1, wherein said debug mode control circuit compares a level of said input voltage with a predetermined level of voltage and generates said debug mode activation signal when said level of said input voltage is higher than said predetermined level of voltage.

3. The semiconductor memory device according to claim 2, wherein said predetermined level of voltage is determined by an external power supply voltage.

4. The semiconductor memory device according to claim 1, wherein said debug mode control circuit generates said debug mode activation signal in response to a level of said input voltage received at a single terminal unused by said system in said normal operation.

5. The semiconductor memory device according to claim 1, wherein:
said debug mode is formed of a plurality of modes;
there are included at least two said terminal unused by said system in said normal operation;
said input voltage is impressed to a first terminal of said terminal unused by said system in said normal operation; and
a second terminal of said terminal unused by said system in said normal operation distinguished from said first terminal receives a mode select signal provided for selecting said plurality of modes.

6. The semiconductor memory device according to claim 5, wherein:
said second terminal is a single terminal;
said first terminal has said input voltage impressed thereto and also receives a clock signal; and
said debug mode control circuit includes at least one shift register, and changes an internal state in response to said clock signal input to said first terminal, and generates said debug mode activation signal in accordance with a combination of said internal state and said mode select signal input to said second terminal.

7. The semiconductor memory device according to claim 5, said internal circuit includes internal signal monitor circuit capable of monitoring a status of an internal signal, wherein:
said internal signal monitor circuit is activated by said debug mode activation signal to externally provide notification of said internal signal in status through a terminal unused by said system in said normal operation.

8. The semiconductor memory device according to claim 7, wherein:
said internal signal monitor circuit is activated by said debug mode activation signal to output said status of said internal signal to said debug mode control circuit; and
said debug mode control circuit externally provides through said second terminal notification of said status of said internal signal received from said internal signal monitor circuit.

9. The semiconductor memory device according to claim 5, said internal circuit includes a signal history record and output circuit capable of recording a history of a variation in status of an internal signal, wherein:
said signal history record and output circuit is activated by said debug mode activation signal to hold variation in status of said internal signal and externally provide notification of a history of said variation in status of said internal signal externally through a terminal unused by said system in said normal operation.

10. The semiconductor memory device according to claim 9, wherein:
said signal history record and output circuit is activated by said debug mode activation signal to hold and output said variation in status of said internal signal to said debug mode control circuit; and
said debug mode control circuit provides through said second terminal notification externally of a history of said variation in status of said internal signal received from said signal history record and output circuit.

11. The semiconductor memory device according to claim 1, wherein said internal circuit includes:
a reference voltage generation circuit generating and outputting a reference voltage serving as a reference for an internal supply voltage; and
an internal voltage generation circuit outputting an internal supply voltage in accordance with said reference voltage output from said reference voltage generation circuit, wherein;
said reference voltage generation circuit is activated by said debug mode activation signal to generate a reference voltage different in potential from a reference voltage which said reference voltage generation circuit outputs in normal operation.

12. The semiconductor memory device according to claim 11, wherein said reference voltage generation circuit is activated by said debug mode activation signal to generate said reference voltage having a voltage level of an external power supply voltage.

13. The semiconductor memory device according to claim 1, wherein:
said internal circuit includes a data input/output circuit externally communicating data, wherein:
said data input/output circuit is activated by said debug mode activation signal to operate to provide a different ability to drive externally outputting internal data from a ability which said data input/output circuit has in normal operation.

14. The semiconductor memory device according to claim 13, wherein said data input/output circuit is activated by said debug mode activation signal to operate to provide a smaller amount of current output by a drive element driven in response to a logical level of said internal data than amount of current which said data input/output circuit outputs in normal operation.
